(19) United States
(12) Patent Application Publication
(10) Pub. No.: US 2025/0149478 A1
(43) Pub. Date: May 8, 2025

(54) SEMICONDUCTOR PACKAGE

(71) Applicant: SAMSUNG ELECTRONICS CO., LTD., Suwon-si (KR)

(72) Inventors: Yongho KIM, Suwon-si (KR); Sunoo KIM, Suwon-si (KR); Jaehee OH, Suwon-si (KR)

(73) Assignee: SAMSUNG ELECTRONICS CO., LTD., Suwon-si (KR)

(21) Appl. No.: 18/630,470

(22) Filed: Apr. 9, 2024

(30) Foreign Application Priority Data
Nov. 7, 2023 (KR) 10-2023-0152998

(51) Int. Cl. H01L 23/00

(52) U.S. Cl. CPC H01L 24/06; H01L 24/14; H01L 24/16; H01L 24/05; H01L 24/13; H01L 2224/0401; H01L 2224/05647; H01L 2224/0603; H01L 2224/13111; H01L 2224/1403; H01L 2224/16145; H01L 2224/16227

(57) ABSTRACT

A semiconductor package includes: a first substrate that comprises a central area and a peripheral area surrounding the central area; a first pad on the first substrate in the central area; a second pad on the first substrate in the peripheral area; a first solder on and coupled to the first pad; and a second solder on and coupled to the second pad, wherein the first pad has a first recess from a top surface of the first pad, wherein the second pad has a second recess from a top surface of the second pad, wherein a width of the second recess is greater than a width of the first recess, and wherein a volume of the second solder is greater than a volume of the first solder.

### CROSS-REFERENCE TO RELATED APPLICATION

This application is based on and claims priority under 35 U.S.C. § 119 to Korean Patent Application No. 10-2023-0152998, filed on Nov. 7, 2023, in the Korean Intellectual Property Office, the disclosure of which is incorporated by reference herein in its entirety.

### BACKGROUND

The disclosure relates to a semiconductor package and a method of fabricating the same, and more particularly, to a semiconductor package having a solder ball and a method of fabricating the same.

Trends in today's electronics industries are to fabricate lightweight, compact, high speed, multi-functionality, and high performance products at reasonable prices. A multi-chip stacked package technique or a system-in-package technique is used to meet these trends. In relation to a multi-chip stacked package or a system-in-package, one semiconductor package may perform functions of a number of unit semiconductor devices. Although the multi-chip stacked package or the system-in-package may be somewhat thicker than a typical single chip package, they have a planar size similar to that of a single chip package, and thus, are primarily used for high-end, compact, and portable products, such as mobile phones, laptop computers, memory cards, or portable camcorders.

A semiconductor device generally uses a metal bump as an electrical connection terminal or a dummy terminal. Shape abnormality of the metal bump may lead to yield drops or process failure, and induce the semiconductor device to have inferior electrical characteristics. It is therefore essential to form solder balls (or solders) without shape abnormality when a semiconductor device is fabricated.

### SUMMARY

Provided are a semiconductor package having improved structural stability and driving stability and a method of fabricating the same.

Provided are a method of fabricating a semiconductor package with less occurrence of failure and a semiconductor package fabricated by the same.

The aspects of the disclosure are not limited to the mentioned above, and other aspects which have not been mentioned above will be clearly understood to those skilled in the art from the following description.

According to an aspect of the disclosure, a semiconductor package includes: a first substrate that comprises a central area and a peripheral area surrounding the central area; a first pad on the first substrate in the central area; a second pad on the first substrate in the peripheral area; a first solder on and coupled to the first pad; and a second solder on and coupled to the second pad, wherein the first pad has a first recess from a top surface of the first pad, wherein the second pad has a second recess from a top surface of the second pad, wherein a width of the second recess is greater than a width of the first recess, and wherein a volume of the second solder is greater than a volume of the first solder.

According to an aspect of the disclosure, a semiconductor package includes: a semiconductor chip that has a first region and a second region spaced apart from the first region; a first pad on the semiconductor chip in the first region; a second pad on the semiconductor chip in the second region; a first solder on and coupled to the first pad; and a second solder on and coupled to the second pad, wherein the first pad has a first recess from a top surface of the first pad, wherein the second pad has a second recess from a top surface of the second pad, wherein a volume of an inner section of the second recess is greater than a volume of an inner section of the first recess, and wherein a height of the first solder is about 90% to about 100% of a height of the second solder.

According to an aspect of the disclosure, a semiconductor package includes: a first substrate; a plurality of first pads on the first substrate; a second substrate on the first substrate; a plurality of second pads on the second substrate; and a plurality of solders that respectively connect the plurality of first pads to the plurality of second pads, wherein the plurality of first pads have recesses recessed from top surfaces of the first pads, wherein widths of the recesses increase in a direction from a center of the first substrate toward an outer lateral surface of the first substrate, and wherein heights of the plurality of solders increase in the direction from the center of the first substrate toward the outer lateral surface of the first substrate.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 illustrates a cross-sectional view showing a semiconductor package according to some embodiments of the disclosure;

FIG. 2 illustrates an enlarged view showing sections A and B of FIG. 1;

FIGS. 3 to 5 illustrate plan views showing pads of a semiconductor package according to some embodiments of the disclosure;

FIG. 6 illustrates a cross-sectional view showing a semiconductor package according to some embodiments of the disclosure;

FIG. 7 illustrates an enlarged view showing sections C, D, and E of FIG. 6;

FIGS. 8 to 12 illustrate cross-sectional views showing a semiconductor package according to some embodiments of the disclosure;

FIGS. 13 to 18 illustrate cross-sectional views showing a method of fabricating a semiconductor package according to some embodiments of the disclosure;

### DETAILED DESCRIPTION

The following will now describe a semiconductor package according to the disclosure with reference to the accompanying drawings.

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’.

The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” refers to any device, system, or part thereof that controls at least one operation. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. As an additional example, the expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

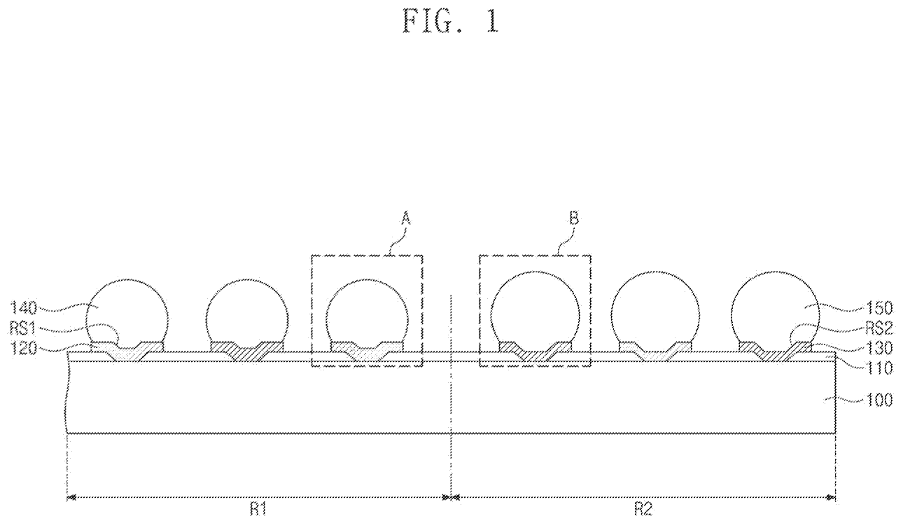

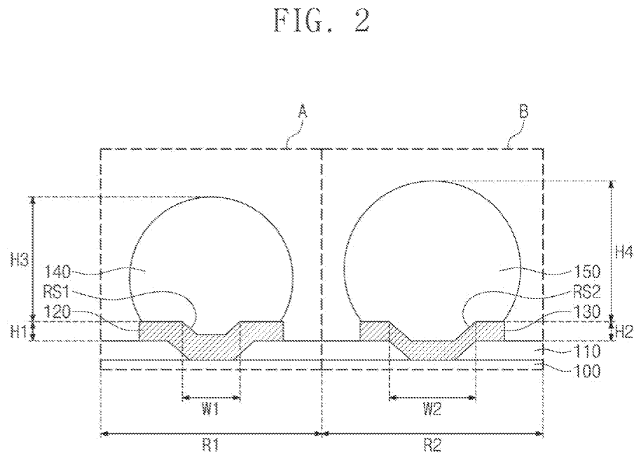

FIG. 1 illustrates a cross-sectional view showing a semiconductor package according to some embodiments of the disclosure. FIG. 2 illustrates an enlarged view showing sections A and B of FIG. 1. FIGS. 3 to 5 illustrate plan views showing pads of a semiconductor package according to some embodiments of the disclosure.

Referring to FIGS. 1 and 2, a substrate 100 may be provided. The substrate 100 may include or correspond to a semiconductor substrate, such as a semiconductor wafer. The substrate 100 may be a bulk silicon substrate, a silicon-on-insulator (SOI) substrate, a germanium substrate, a germanium-on-insulator (GOI) substrate, a silicon-germanium (SiGe) substrate, or an epitaxial film substrate obtained by performing selective epitaxial growth (SEG). The substrate 100 may include, for example, at least one selected from silicon (Si), germanium (Ge), silicon germanium (SiGe), gallium arsenic (GaAs), indium gallium arsenic (InGaAs), aluminum gallium arsenic (AlGaAs), and a mixture of those components. When the substrate 100 is a semiconductor substrate, the substrate 100 may include an integrated circuit. The substrate 100 may be a semiconductor chip including an electronic device such as transistors. For example, the substrate 100 may be a wafer-level die formed of a semiconductor such as silicon (Si).

In an embodiment, the substrate 100 may further include a wiring layer including dielectric layers (that cover the integrated circuit) and wiring patterns (that are in the dielectric layers and connected to the integrated circuit).

In an embodiment, the substrate 100 may be a package substrate for mounting a semiconductor package on an external apparatus, a motherboard, or other substrate. Alternatively, the substrate 100 may be an interposer to redistribute semiconductor chips of a semiconductor package and to connect the semiconductor chips to a package substrate of the semiconductor package. For example, the substrate 100 may be a printed circuit board (PCB) having a signal pattern or a redistribution substrate having a plurality of wiring layers.

The substrate 100 may have a first region R1 and a second region R2, which may be distinguished without overlapping each other. FIG. 1 depicts that the first region R1 and the second region R2 are in contact with each other, but described embodiment. The first region R1 and the second region R2 may be spaced apart from each other. The following description will focus on the embodiment of FIG. 1. The first region R1 and the second region R2 may be areas defined based on a shape of the substrate 100. For example, the first region R1 may be an area positioned on a central portion of the substrate 100, and the second region R2 may be an area positioned on an edge of the substrate 100. The first region R1 may be a central area of the first substrate 100, and the second region R2 may be a peripheral area that surrounds the first region R1.

In some embodiments, a protection layer 110 may be provided on the substrate 100. The protection layer 110 may cover a top surface of the substrate 100. The protection layer 110 may cover all of the first region R1 and the second region R2. The protection layer 110 may include a dielectric material. For example, the protection layer 110 may include oxide, nitride, or oxynitride of a material included in the substrate 100. The protection layer 110 may include, for example, silicon oxide, silicon nitride, or silicon oxynitride. Alternatively, the protection layer 110 may include a photosensitive material. For example, the protection layer 110 may include a photo-imagable dielectric (PID). In detail, the photo-imagable dielectric may include at least one selected from photosensitive polyimide (PI), polybenzoxazole (PBO), phenolic polymers, and benzocyclobutene polymers.

The substrate 100 may be provided with first pads 120 and second pads 130 on the top surface of the substrate 100. The first pads 120 and the second pads 130 may be positioned on the protection layer 110. The first pads 120 and the second pads 130 may be electrically connected to the substrate 100. For example, the first pads 120 and the second pads 130 may be provided to electrically connect the integrated circuit in the substrate 100 to an external apparatus or other semiconductor device. In the disclosure, the phrase “electrically connected/coupled” may include “directly connected/coupled” or “indirectly connected/coupled through other conductive component(s).” The first pads 120 and the second pads 130 may include metal. For example, the first pads 120 and the second pads 130 may include copper (Cu).

The first pads 120 and the second pads 130 may each have a damascene structure. That is, the first pads 120 and the second pads 130 may each have a head part and a tail part that are connected into a single unitary piece. Each of the first pads 120 and the second pads 130 may have a T-shaped cross-section in the head part and the tail part.

The head parts of the first pads 120 and the second pads 130 may each be a pad part to which is coupled a connection terminal of an external apparatus or other semiconductor device or a wiring part that horizontally expands a wiring line on the protection layer 110. The head parts may be provided on a top surface of the protection layer 110. For example, the head parts may protrude onto the top surface of the protection layer 110.

The tail parts of the first pads 120 and the second pads 130 may each be via parts that vertically connect the first pads 120 and the second pads 130 to the integrated circuits of the substrate 100 or to the substrate 100, for example, wiring lines formed in the substrate 100. The tail parts may couple the head parts to the substrate 100. For example, the tail parts of the first pads 120 and the second pads 130 may each extend from bottom surfaces of the head parts, and may penetrate the protection layer 110 to be coupled to the substrate 100.

The first pads 120 and the second pads 130 may each have a width that is constant regardless of a distance from the top surface of the substrate 100. In this disclosure, the width of each of the first pad 120 and the second pad 130 may be measured in a direction horizontal to the top surface of the substrate 100. In addition, the widths of the first pads 120 and the second pads 130 may refer to widths of the head parts of the first pads 120 and the second pads 130, which are positioned on the protection layer 110. For example, the first pads 120 and the second pads 130 may have their lateral surfaces perpendicular to the top surface of the protection layer 110.

As shown in FIG. 2, in some embodiments, a first height H1 of the first pad 120 may be the same as a height H2 of the second pad 130. In this disclosure, the height H1 of the first pad 120 and the height H2 of the second pad 130 may each be a thickness in a direction horizontal to the top surface of the substrate 100. Moreover, in this disclosure, the height H1 of the first pad 120 and the height H2 of the second pad 130 may indicate a height of the head part of the first pad 120 positioned on the protection layer 110 and a height of the head part of the second pad 130 positioned on the protection layer 110. For example, a distance from the top surface of the substrate 100 to top surfaces of the first pads 120 may be the same as that from the top surface of the substrate 100 to top surfaces of the second pads 130.

As shown in FIG. 2, in some embodiments, the first pads 120 may be disposed on the first region R1 of the substrate 100. The second pads 130 may be disposed on the second region R2 of the substrate 100. The first pads 120 may be disposed spaced apart from each other, and the second pads 130 may be disposed spaced apart from each other. The first pads 120 may be spaced apart from the second pads 130. The first pads 120 may have their widths the same as those of the second pads 130. However, embodiments of the disclosure are not limited thereto. The widths of the first pads 120 may be different from those of the second pads 130. As shown in FIG. 3, the first pads 120 and the second pads 130 may each have a circular planar shape. Alternatively, the first pads 120 and the second pads 130 may each have a linear planar shape, a tetragonal planar shape, or a polygonal planar shape.

The first pads 120 and the second pads 130 may have first recesses RS1 and second recesses RS2, respectively. The first pads 120 may correspondingly have the first recesses RS1 that are inwardly directed from the top surfaces of the first pads 120. For example, the first recesses RS1 may have their shapes recessed from the top surfaces of the first pads 120. When viewed in plan, the first recesses RS1 may be positioned on a central portion of the first pad 120. A distance from the lateral surfaces of the first pads 120 to the first recesses RS1 may be in a range of about 2 micrometers to about 5 micrometers.

The second pads 130 may have their second recesses RS2 inwardly directed from the top surfaces of the second pads 130. For example, the second recesses RS2 may have their shapes recessed from the top surfaces of the second pads 130. When viewed in plan, the second recesses RS2 may be positioned on central portions of the second pads 130. A distance from the lateral surfaces of the second pads 130 to the second recesses RS2 may be in a range of about 2 micrometers to about 5 micrometers.

FIG. 2 depicts that an inner surface of the first recess RS1 is inclined to the top surface of the first pad 120 and an inner surface of the second recess RS2 is inclined to the top surface of the second pad 130, but embodiments of the disclosure are not limited to the above described embodiment. The inner surface of the first recess RS1 may be perpendicular to the top surface of the first pad 120, and the inner surface of the second recess RS2 may be perpendicular to the top surface of the second pad 130.

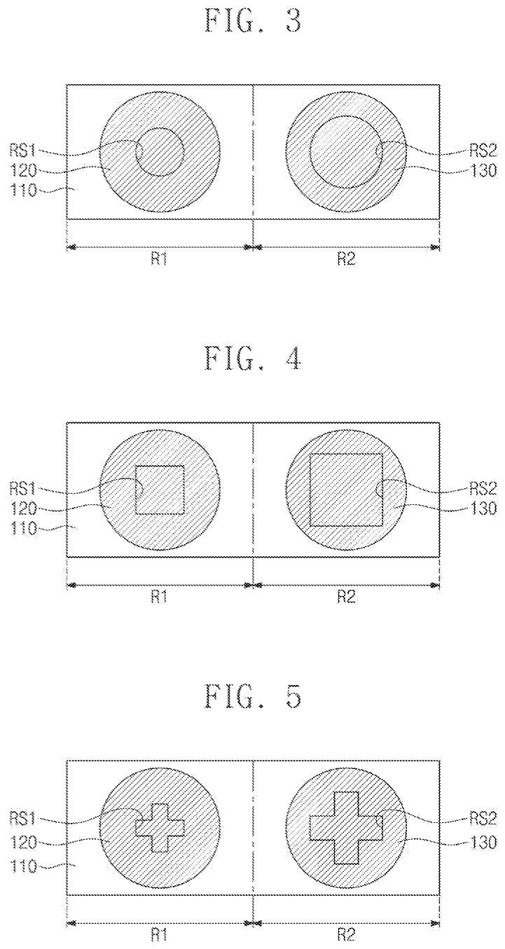

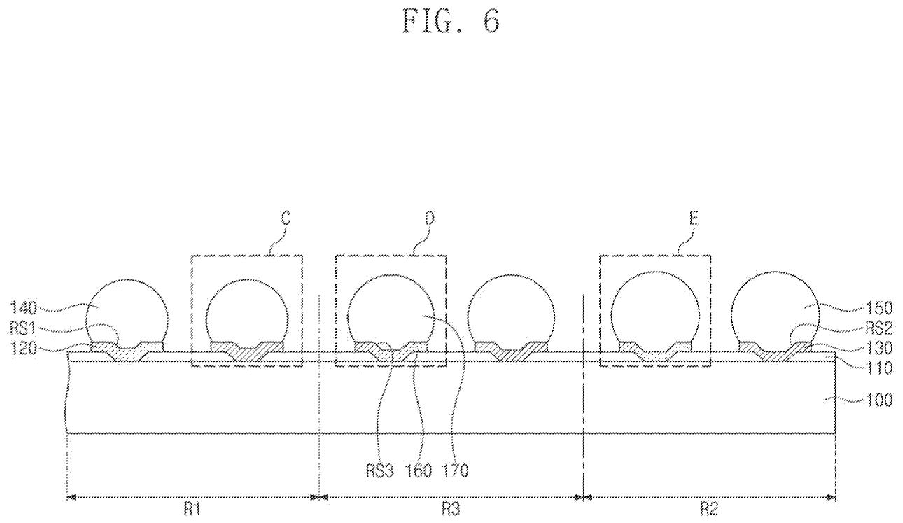

A planar shape of the first recess RS1 and a planar shape of the second recess RS2 may respectively correspond to a planar shape of the first pad 120 and a planar shape of the second pad 130. For example, as shown in FIG. 3, the first recess RS1 and the second recess RS2 may have their circular planar shapes. Alternatively, as shown in FIG. 4, the first recess RS1 and the second recess RS2 may have their polygonal planar shapes such as tetragonal planar shapes. Alternatively, as shown in FIG. 5, the first recess RS1 and the second recess RS2 may have their cross planar shapes.

Referring still to FIG. 2, a first width W1 of the first recesses RS1 may be less than a second width W2 of the second recesses RS2. A depth of each of the first recesses RS1 may be less than that of each of the second recesses RS2. In this disclosure, the depth of the first recesses RS1 may indicate a distance from the top surface of the first pad 120 to a bottom surface of the first recesses RS1. The depth of the second recesses RS2 may indicate a distance from the top surface of the second pad 130 to a bottom surface of the second recesses RS2. However, embodiments of the disclosure are not limited thereto.

According to some embodiments, the depth of the first recesses RS1 may be the same as that of the second recesses RS2. A volume of an inner section of each of first recesses RS1 may be less than that of an inner section of each of second recesses RS2.

According to some embodiments, seed layers may be provided between the first pads 120 and the substrate 100 and between the second pads 130 and the substrate 100. For example, each of the seed layers may be provided on a bottom surface of one of the first pad 120 and the second pad 130. The seed layers may include metal.

According to some embodiments, solders may be provided on the protection layer 110. For example, first solders 140 may be disposed on the first pads 120 on the first region R1, and second solders 150 may be disposed on the second pads 130 on the second region R2. For example, the first pads 120 may be or correspond to under-bump pads for the first solders 140, and the second pads 130 may be or correspond to under-bump pads for the second solders 150.

The first solders 140 may be correspondingly positioned on the first pads 120. The first solders 140 may be coupled to the top surfaces of the first pads 120. On the first pads 120, the first solders 140 may fill the first recesses RS1. The first solders 140 may include a solder material or alloy including tin (Sn).

The second solders 150 may be correspondingly positioned on the second pads 130. The second solders 150 may be coupled to the top surfaces of the second pads 130. On the second pads 130, the second solders 150 may fill the second recesses RS2. The second solders 150 may include a solder material or alloy including tin (Sn).

As shown in FIG. 2, in some embodiments, the height H3 of the first solder 140 may be less than the height H4 of the second solder 150. For example, the height H3 of the first solder 140 may be about 90% to about 100% of the height H4 of the second solder 150. In this disclosure, the height H3 of the first solder 140 may indicate a distance from the top surface of the first pad 120 to an uppermost end of the first solder 140, and the height H4 of the second solder 150 may indicate a distance from the top surface of the second pad 130 to an uppermost end of the second solder 150. A volume of each of the first solders 140 may be less than that of each of the second solders 150.

According to some embodiments of the disclosure, the volume of the second solder 150 on the second region R2 may be greater than that of the first solder 140 on the first region R1. The volume of the inner section of the second recesses RS2 of the second pad 130 may be greater than that of the inner section of the first recesses RS1 of the first pad 120. Therefore, the volume of the first solder 140 that fills the first recesses RS1 may be greater than that of the second solder 150 that fills the second recesses RS2, and thus, although there is a difference in volume between the first solders 140 and the second solders 150, upper ends of the second solders 150 may be located at a level the same as or similar to that of upper ends of the first solders 140. This embodiments of the disclosure may prevent the first solders 140 from failure such as no contact with other apparatus, chip, or device when the substrate 100 is mounted on the other apparatus, chip, or device.

In the embodiments that follow, a detailed description of technical features repetitive to those discussed with reference to FIGS. 1 to 5 will be omitted and differences of the embodiments will be discussed in detail. The same components as those of the semiconductor device discussed above will be allocated the same reference numerals thereto.

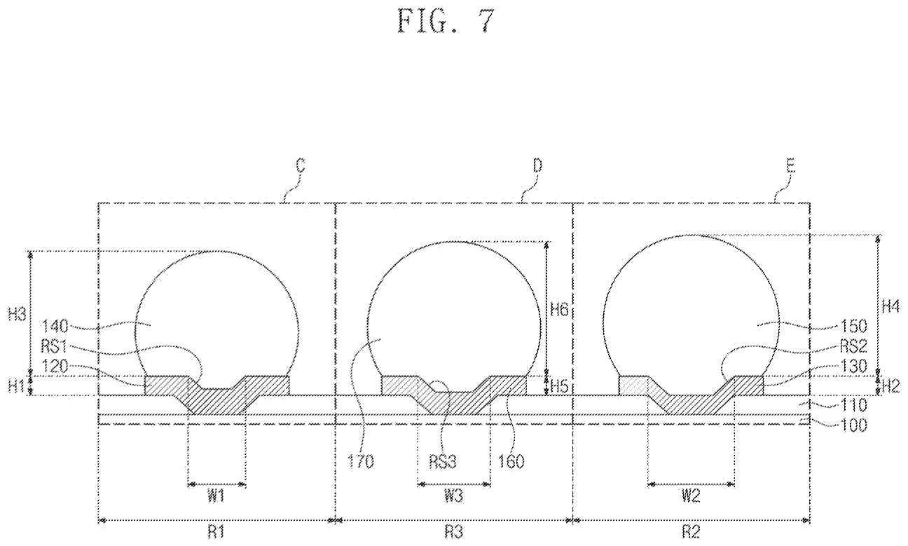

FIG. 6 illustrates a cross-sectional view showing a semiconductor package according to some embodiments of the disclosure. FIG. 7 illustrates an enlarged view showing sections C, D, and E of FIG. 6.

Referring to FIGS. 6 and 7, the substrate 100 may further include a third region R3 interposed between the first region R1 and the second region R2. The third region R3 may separate the first region R1 and the second region R2 from each other. The third region R3 may be an intermediate area positioned between the first region R1 as a central area and the second region R2 as a peripheral area.

On the third region R3, third pads 160 may be provided on the top surface of the substrate 100. The third pads 160 may be positioned on the protection layer 110. The third pads 160 may be disposed spaced apart from each other. The third pads 160 may be electrically connected to the substrate 100. The third pads 160 may each have a damascene structure. That is, the third pads 160 may each have a head part and a tail part that are connected into a single unitary piece. The head part and the tail part of the third pads 160 may have a T-shaped cross-section. The head part may be provided on the top surface of the protection layer 110. The tail part may extend from a bottom surface of the head part, and may penetrate the protection layer 110 to be coupled to the substrate 100.

A width of the third pad 160 may be constant regardless of a distance from the top surface of the substrate 100. For example, the third pads 160 may have their lateral surfaces perpendicular to the top surface of the protection layer 110. As shown in FIG. 7, in some embodiments, a height H5 of the third pad 160 may be the same as the height H1 of the first pad 120 and the height H2 of the second pad 130.

The widths of the third pads 160 may be the same as those of the first pads 120 and those of the second pads 130. In some embodiments, the third pads 160 may have their circular planar shapes. Alternatively, the third pads 160 may have their linear planar shapes or polygonal planar shapes such as tetragonal planar shapes.

Each of the third pads 160 may have a third recess RS3 inwardly directed from a top surface of the third pad 160. For example, as shown in FIG. 6, the third recesses RS3 may have their shapes recessed from the top surfaces of the third pads 160. When viewed in plan, the third recesses RS3 may be positioned on central portions of the third pads 160. A distance from the lateral surfaces of the third pads 160 to the third recesses RS3 may be in a range of about 2 micrometers to about 5 micrometers. FIG. 7 depicts that inner surfaces of the third recesses RS3 are inclined to the top surfaces of the third pads 160, but embodiments of the disclosure are not limited to the above described embodiment. The inner surfaces of the third recesses RS3 may be perpendicular to the top surfaces of the third pads 160. The third recesses RS3 may have their planar shapes that correspond to those of the third pads 160. For example, the third recesses RS3 may have their circular planar shapes, cross planar shapes, or polygonal planar shapes such as tetragonal planar shapes.

As shown in FIG. 7, a third width W3 of the third recess RS3 may be greater than the first width W1 of the first recesses RS1 and less than the second width W2 of the second recesses RS2. A depth of each of the third recesses RS3 may be greater than that of each of the first recesses RS1 and less than that of each of the second recesses RS2. However, embodiments of the disclosure are not limited thereto. According to some embodiments, the depth of each of the third recesses RS3 may be the same as that of each of the first recesses RS1 and that of each of the second recesses RS2. A volume of an inner section of each third recess RS3 may be greater than that of the inner section of each first recesses RS1 and less than that of the inner section of each second recesses RS2.

In some embodiments, seed layers may be provided between the third pads 160 and the substrate 100. For example, each of the seed layers may be provided on the top surface of one of the third pads 160.

On the third region R3, third solders 170 may be disposed on the third pads 160. The third solders 170 may be correspondingly positioned on the third pads 160. The third solders 170 may be coupled to the top surfaces of the third pads 160. On the third pads 160, the third solders 170 may fill the third recesses RS3.

A height H6 of the third solder 170 may be greater than the height H3 of the first solder 140 and less than the height H4 of the second solder 150. A volume of each of the third solders 170 may be greater than that of each of the first solders 140 and less than that of each of the second solders 150.

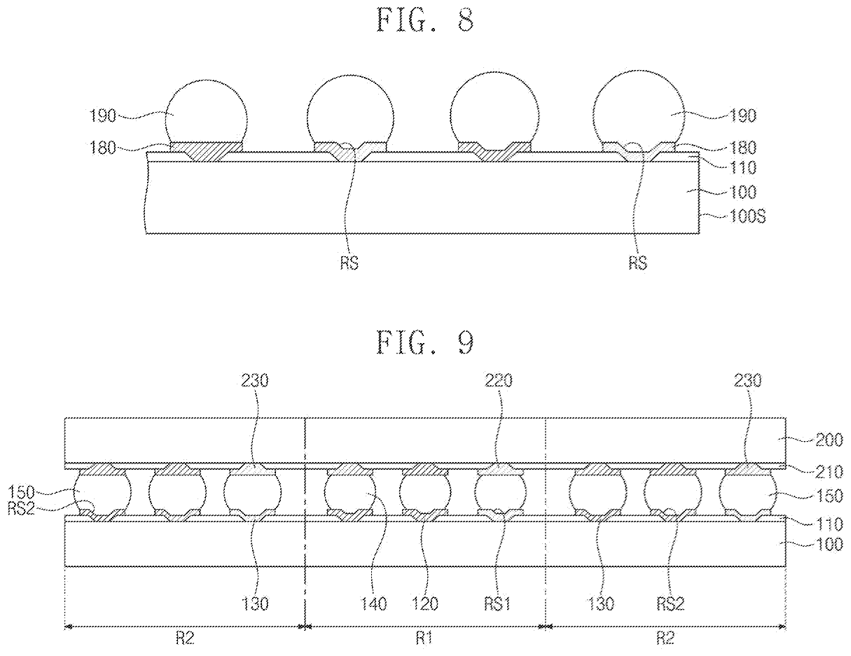

FIG. 8 illustrates a cross-sectional view showing a semiconductor package according to some embodiments of the disclosure.

Referring to FIG. 8, a substrate 100 may be provided. A protection layer 110 may be provided on the substrate 100. The substrate 100 may be provided with pads 180 on a top surface of the substrate 100. The pads 180 may be positioned on the protection layer 110. The pads 180 may each have a damascene structure. That is, the pads 180 may each have a head part and a tail part that are connected into a single unitary piece. A width of each of the pads 180 may be constant regardless of a distance from the top surface of the substrate 100. The pads 180 may have the same height.

The pads 180 may have their recesses RS inwardly directed from top surfaces of the pads 180. For example, the recesses RS may have their shapes recessed from the top surfaces of the pads 180. In some embodiments, when viewed in plan, the recesses RS may be positioned on central portions of the pads 180.

The recesses RS may have their widths that decrease with increasing distance from a lateral surface 100s of the substrate 100. The recesses RS may have their inner sections whose volumes decrease with increasing distance from the lateral surface 100s of the substrate 100. One or more pads 180 positioned far away from the lateral surface 100s of the substrate 100, (for example, one or more pads 180 positioned on a central portion of the substrate 100) may not have the recesses RS. For example, the one or more pads 180 may have flat top surfaces.

In some embodiments, solders 190 may be provided on the protection layer 110. For example, the solders 190 may be disposed on the pads 180. The solders 190 may be correspondingly positioned on the pads 180. The solders 190 may be coupled to the top surfaces of the pads 180. On the pads 180, the solders 190 may fill the recesses RS.

The solders 190 may have their heights that decrease with increasing distance from the lateral surface 100s of the substrate 100. For example, the smallest one of the heights of the solders 190 may be about 90% to about 100% of the largest one of the height of the solders 190. The solders 190 may have their volumes that decrease with increasing distance from the lateral surface 100s of the substrate 100.

FIG. 9 illustrates a cross-sectional view showing a semiconductor package according to some embodiments of the disclosure.

Referring to FIG. 9, a first substrate 100 may be provided. The first substrate 100 may be a wiring substrate, a semiconductor substrate on which a semiconductor device is provided, or a semiconductor chip. The first substrate 100 may correspond to the substrate 100 discussed with reference to FIG. 1. The first substrate 100 may have a first region R1 as a central area and a second region R2 as a peripheral area that surrounds the first region R1. A first protection layer 110 may be provided on the first substrate 100. On the first region R1, first pads 120 may be provided on the first protection layer 110. The first pads 120 may have their first recesses RS1 on top surfaces of the first pads 120. On the second region R2, second pads 130 may be provided on the first protection layer 110. The second pads 130 may have, on their top surfaces, second recesses RS2 larger than the first recesses RS1. First solders 140 may be provided on the first pads 120. Second solders 150 may be provided on the second pads 130.

A second substrate 200 may be provided. The second substrate 200 may be a wiring substrate, a semiconductor substrate on which a semiconductor device is provided, or a semiconductor chip. A second protection layer 210 may be formed on a bottom surface of the second substrate 200. The second protection layer 210 may be provided with fourth pads 220 and fifth pads 230 on a bottom surface of the second protection layer 210. On the first region R1, the fourth pads 220 may be provided on positions that correspond to those of the first pads 120, and on the second region R2, the fifth pads 230 may be provided on positions that correspond to those of the second pads 130.

As shown in FIG. 9, in some embodiments, the first solder 140 and the second solder 150 may be provided between the first substrate 100 and the second substrate 200. The first solders 140 may connect the first pads 120 to the fourth pads 220. The second solders 150 may connect the second pads 130 to the fifth pads 230. A volume of each of the first solders 140 may be less than that of each of the second solders 150. On the first region R1, a first distance may be provided between the first substrate 100 and the second substrate 200, for example, between the top surfaces of the first pads 120 and bottom surfaces of the fourth pads 220. On the second region R2, a second distance may be provided between the first substrate 100 and the second substrate 200, for example, between the top surfaces of the second pads 130 and bottom surfaces of the fifth pads 230. The second distance may be about 90% to about 100% of the first distance.

According to some embodiments of the disclosure, a volume of the second solder 150 on the second region R2 may be greater than that of the first solder 140 on the first region R1. A volume of an inner section of the second recesses RS2 of the second pad 130 may be greater than that of an inner section of the first recesses RS1 of the first pad 120. Therefore, although there is a difference in volume between the first solders 140 and the second solders 150, a distance between the first pads 120 and the fourth pads 220 may be the same as or similar to that between the second pads 130 and the fifth pads 230. This configuration may prevent the solders 140 and 150 from failure such as no contact with each other when the first substrate 100 and the second substrate 200 are mounted.

According to some embodiments of the disclosure, heights of the solders 140 and 150 may be controlled by using sizes of the recesses RS1 and RS2 formed on the first pads 120 and the second pads 130. In addition, this configuration may prevent the solders 140 and 150 from failure such as no contact with each other even when the substrates 100 and 200 are warped.

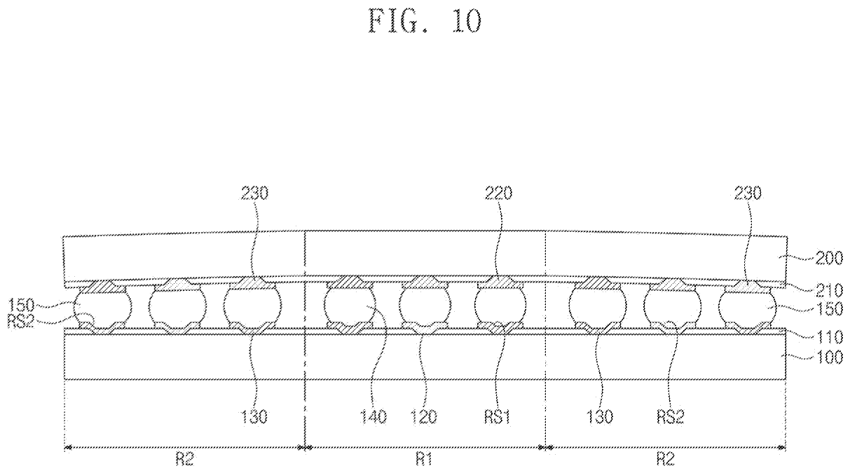

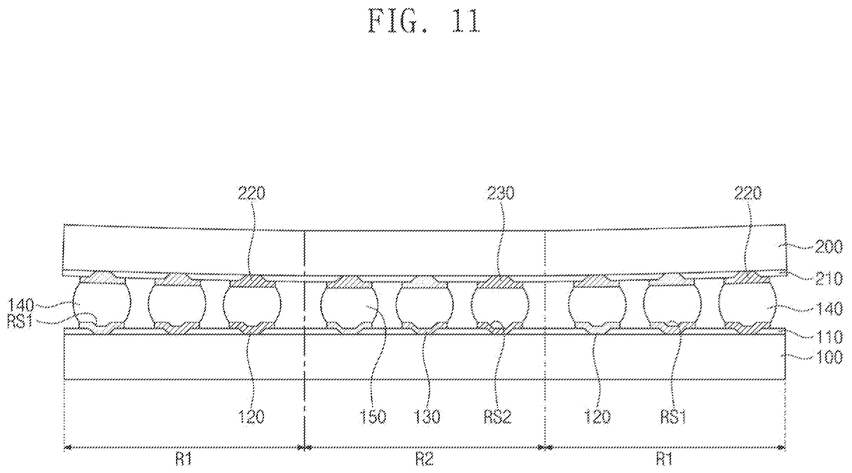

FIGS. 10 and 11 illustrate cross-sectional views showing a semiconductor package according to some embodiments of the disclosure.

As shown in FIG. 10, the second substrate 200 may suffer from warpage caused by heat provided when the second substrate 200 is mounted on the first substrate 100. For example, referring to FIG. 10, the second substrate 200 may be bent into a cry shape or an inverse U shape. For example, on the bottom surface of the second substrate 200, the first region or a central area of the second substrate 200 may have a shape recessed (or concave) more than the second region R2 or a peripheral area of the second substrate 200. When viewed in cross-section, the first region R1 of the second substrate 200 may be located at a higher level than that of the second region R2 of the second substrate 200. In this case, the first recesses RS1 may have small sizes on the first region R1 on which a large distance is provided between the first pads 120 and the fourth pads 220. For example, on the first pads 120, the first solders 140 may have reduced heights. The second recesses RS2 may have large sizes on the second region R2 on which a small distance is provided between the second pads 130 and the fifth pads 230. For example, on the second pads 130, the second solders 150 may have increased heights.

Alternatively, as shown in FIG. 11, the second substrate 200 may be bent into a smile shape or a U shape. For example, on the bottom surface of the second substrate 200, a central area of the second substrate 200 may have a shape protruding (or convex) more than a peripheral area of the second substrate 200. When viewed in cross-section, the central area of the second substrate 200 may be located at a lower level than that of the peripheral area of the second substrate 200. In this case, the central area of the second substrate 200 may correspond to the second region R2 of the second substrate 200, and the peripheral area of the second substrate 200 may correspond to the first region R1 of the second substrate 200. When viewed in cross-section, the first region R1 of the second substrate 200 may be located at a higher level than that of the second region R2 of the second substrate 200. In this case, the first recesses RS1 may have small sizes on the first region R1 on which a large distance is provided between the first pads 120 and the fourth pads 220. For example, on the first pads 120, the first solders 140 may have increased heights. The second recesses RS2 may have large sizes on the second region R2 on which a small distance is provided between the second pads 130 and the fifth pads 230. For example, on the second pads 130, the second solders 150 may have reduced heights.

According to some embodiments of the disclosure, heights of the solders 140 and 150 may be adjusted based on a distance between the first substrate 100 and the second substrate 200. This configuration may prevent the solders 140 and 150 from failure such as no contact with each other when the first substrate 100 and the second substrate 200 are mounted.

FIG. 12 illustrates a cross-sectional view showing a semiconductor package according to some embodiments of the disclosure.

Referring to FIG. 12, a first semiconductor chip 300 may be provided. The first semiconductor chip 300 may include a first semiconductor substrate, an integrated circuit and a wiring layer formed on the first semiconductor substrate, first lower pads 320 provided on a bottom surface of the first semiconductor substrate, first upper pads 350 provided on a top surface of the first semiconductor substrate, first through vias 340 that vertically penetrate the first semiconductor substrate to connect the first lower pads 320 to the first upper pads 350 or to connect the integrated circuit to the first upper pads 350. External terminals 305 may be coupled to the first lower pads 320. According to some embodiments, a wiring substrate may be provided instead of the first semiconductor chip 300.

A chip stack may be disposed on the first semiconductor chip 300. The chip stack may include one or more second semiconductor chips 400 stacked on the first semiconductor chip 300. Each of the second semiconductor chips 400 may be a memory chip, such as dynamic random access memory (DRAM), static random access memory (SRAM), magnetoresistive random access memory (MRAM), or Flash memory. Alternatively, each of the second semiconductor chips 400 may be a logic chip. The second semiconductor chips 400 may have their widths each of which is less than that of the first semiconductor chip 300. FIG. 12 depicts that one chip stack is provided, but embodiments of the disclosure are not limited to the above described embodiment. When the chip stack is provided in plural, the plurality of chip stacks may be spaced apart from each other on the first semiconductor chip 300. In the following description, the second semiconductor chips 400 will be discussed based on a lowermost second semiconductor chip 400.

The second semiconductor chip 400 may correspond to a device including the substrate 100, the protection layer 110, the first pad 120, and the second pad130 discussed with reference to FIGS. 1 to 8. The second semiconductor chip 400 may include a second semiconductor substrate 410, a protection layer 420, second lower pads 430, second through vias 440, and second upper pads 450.

The second semiconductor substrate 410 may include a semiconductor material. For example, the second semiconductor substrate 410 may be a monocrystalline silicon (Si) substrate. A bottom surface of the second semiconductor substrate 410 may be an active surface, and a top surface of the second semiconductor substrate 410 may be an inactive surface.

An integrated circuit may be provided on the bottom surface of the second semiconductor substrate 410. For example, the integrated circuit may be a memory circuit. For example, the second semiconductor chip 400 may be a memory chip. For another example, the integrated circuit may be a logic circuit. The integrated circuit may include a dielectric pattern, a wiring pattern, and an electronic element such as a transistor.

The protection layer 420 may be provided on the bottom surface of the second semiconductor substrate 410. On the bottom surface of the second semiconductor substrate 410, the protection layer 420 may cover and protect the integrated circuit.

The second lower pad 430 may be disposed on the bottom surface of the second semiconductor substrate 410. The second lower pad 430 may be disposed on a bottom surface of the protection layer 420. The second lower pad 430 may be electrically connected to the integrated circuit. The second lower pad 430 may be provided in plural. The plurality of second lower pads 430 may be front pads of the second semiconductor chip 400. The second lower pads 430 may correspond to the pads 120 and 130 discussed with reference to FIGS. 1 to 8. For example, the second lower pads 430 may have their recesses on bottom surfaces of the second lower pads 430. The recesses may have their sizes that increase with decreasing distance from a lateral surface of the second semiconductor chip 400.

The second upper pads 450 may be disposed on the top surface of the second semiconductor substrate 410. The second upper pads 450 may have flat bottom surfaces.

The second through vias 440 may vertically penetrate the second semiconductor substrate 410 to connect the second lower pads 430 to the second upper pads 450.

The second semiconductor chips 400 may be substantially the same as each other. In an embodiment, an uppermost second semiconductor chip 400 may not include the second through vias 440 or the second upper pads 450. In addition, the upper second semiconductor chip 400 may have a thickness greater than those of other second semiconductor chips 400.

The second semiconductor chips 400 may be electrically connected to each other. For example, connection terminals 460 may be provided on the second lower pads 430 of the second semiconductor chips 400. The connection terminals 460 may connect the second lower pads 430 to the second upper pads 450 of an underlying second semiconductor chip 400. The connection terminals 460 may have their volumes that increase with decreasing distance from the lateral surfaces of the second semiconductor chips 400. However, the recesses formed on the second lower pads 430 may have their sizes that increase with decreasing distance from the lateral surfaces of the second semiconductor chips 400. It may therefore be prevented that the connection terminals 460 having large volumes inhibit the connection terminals 460 have small volumes from being coupled to the second lower pads 430 or the second upper pads 450, or that the connection terminals 460 having large volumes protrude to contact other connection terminals 460. Accordingly, it may be possible to provide a semiconductor package with structural and operating stability.

The chip stack may be mounted on the first semiconductor chip 300. The chip stack may be disposed on the first semiconductor chip 300. The first upper pads 350 of the first semiconductor chip 300 may be vertically aligned with the second lower pads 430 of a lowermost second semiconductor chip 400 of the chip stack. The connection terminals 460 may be provided between the first upper pads 350 and the second lower pads 430. The connection terminals 460 may connect the first upper pads 350 to the second lower pads 430.

In an embodiment, an underfill layer may be provided between the second semiconductor chips 400 and between the lowermost second semiconductor chip 400 and the first semiconductor chip 300. The underfill layer may fill a space between the second semiconductor chips 400 and space between the lowermost second semiconductor chip 400 and the first semiconductor chip 300. The underfill layer may surround the connection terminal 460.

On the first semiconductor chip 300, a molding layer 500 may surround the second semiconductor chips 400. The molding layer 500 may protect the second semiconductor chips 400. The molding layer 500 may include a dielectric material. For example, the molding layer 500 may include an epoxy molding compound (EMC).

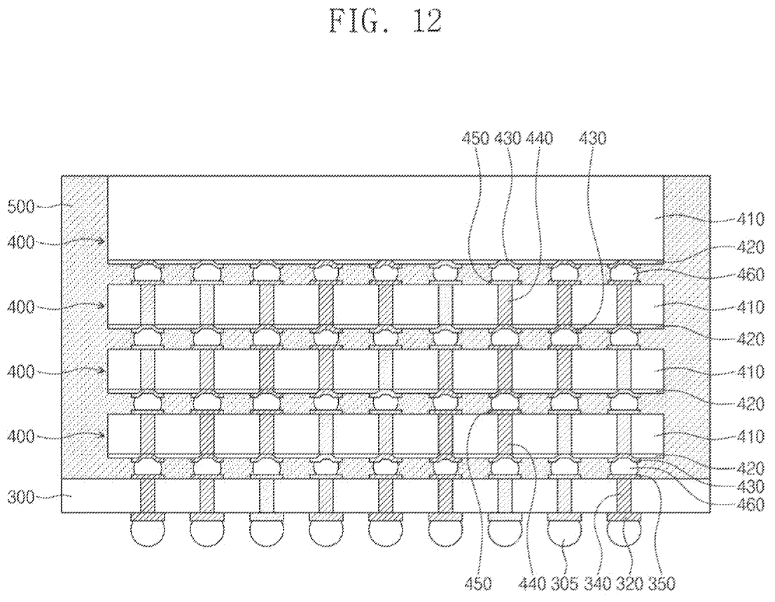

FIGS. 13 to 18 illustrate cross-sectional views showing a method of fabricating a semiconductor package according to some embodiments of the disclosure.

Referring to FIG. 13, a substrate 100 may be provided. The substrate 100 may include a semiconductor substrate. For example, the substrate 100 may be a semiconductor substrate such as a semiconductor wafer. The substrate 100 may be provided thereon with a memory circuit, a logic circuit, or a combination of the memory circuit and the logic circuit. When the substrate 100 is a semiconductor substrate, the substrate 100 may include an integrated circuit therein. The substrate 100 may be a semiconductor chip including an electronic element such as a transistor.

In an embodiment, the substrate 100 may further include a wiring layer including dielectric layers that cover the integrated circuit and wiring patterns that are in the dielectric layers and connected to the integrated circuit.

In an embodiment, the substrate 100 may be a package substrate for mounting a semiconductor package on an external device, a motherboard, or other substrate. Alternatively, the substrate 100 may be an interposer to redistribute semiconductor chips of a semiconductor package and to connect the semiconductor chips to a package substrate of the semiconductor package.

The substrate 100 may have a first region R1 and a second region R2. The first region R1 and the second region R2 may be areas that are distinguished without overlapping each other. The first region R1 may be positioned on a central portion of the substrate 100, and the second region R2 may be positioned on an edge of the substrate 100. For example, the first region R1 may be a central area of the first substrate 100, and the second region R2 may be a peripheral area that surrounds the first region R1.

In some embodiments, the protection layer 110 may be formed on the substrate 100. The protection layer 110 may cover a top surface of the substrate 100. For example, a photosensitive material may be coated and deposited on the substrate 100, and then the photosensitive material may be exposed and developed to form the protection layer 110. The protection layer 110 may have an opening that exposes a wiring pattern formed on the substrate 100.

First pads 120 and second pads 130 may be formed on the protection layer 110. For example, a seed layer may be formed by depositing a metal layer that conformally covers a top surface of the protection layer 110 and inner sidewall and a bottom surface of the opening of the protection layer 110. The seed layer may include a metallic material, such as gold (Au) or silver (Ag). The seed layer may be coupled to the wiring pattern in the opening. A mask pattern may be formed on the seed layer. The mask pattern may have a pattern hole that vertically penetrates the mask pattern to expose the seed layer. The pattern hole may define areas on which the first pads 120 and the second pads 130 are formed in a subsequent process. The pattern hole may be positioned on the opening of the protection layer 110. A plating process may be performed in which the seed layer exposed by the pattern hole of the mask pattern is used as a seed. The plating process may continue until top surfaces of the first pads 120 and the second pads 130 reach a certain height in the pattern hole. The first pads 120 and the second pads 130 may have their substantially flat top surfaces. Afterward, the mask pattern may be removed.

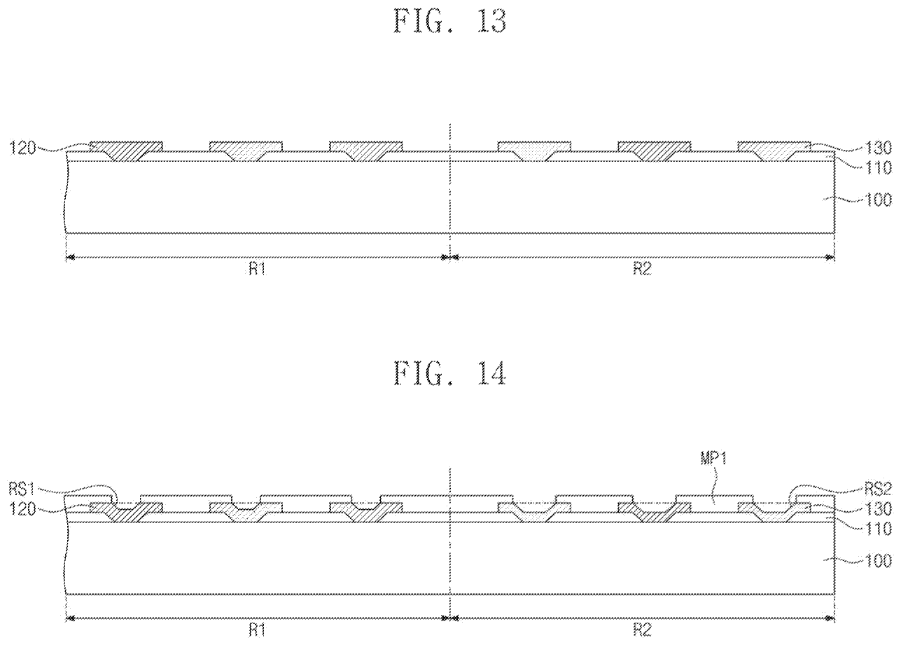

Referring to FIG. 14, the first recesses RS1 may be formed on the first pads 120, and second recesses RS2 may be formed on the second pads 130. For example, a first mask pattern MP1 may be formed on the protection layer 110. The first mask pattern MP1 may cover the first pads 120 and the second pads 130. The first mask pattern MP1 may have pattern holes that expose the first pads 120 and the second pads 130. The pattern holes may define areas where the first recesses RS1 or the second recesses RS2 are formed. The pattern holes positioned on the first pads 120 may have their widths less than those of the pattern holes positioned on the second pads 130. An etching process may be performed on the top surfaces of the first pads 120 exposed by the first mask pattern MP1 and the top surfaces of the second pads 130 exposed by the first mask pattern MP1. The first recesses RS1 formed on the top surfaces of the first pads 120 may have their widths and depths less than those of the second recesses RS2 formed on the top surfaces of the second pads 130.

Referring to FIG. 15, the first mask pattern MP1 may be removed.

A second mask pattern MP2 may be formed on the protection layer 110. The second mask pattern MP2 may cover the first pads 120 and the second pads 130. The second mask pattern MP2 may have pattern holes that expose the first pads 120 and the second pads 130. The pattern holes may define areas where first solder material layers SM1 or second solder material layers SM2 are formed as discussed below. The pattern holes positioned on the first pads 120 may have the same width as that of the pattern holes positioned on the second pads 130. A range of about 2 micrometers to about 5 micrometers may be given as an overlapping distance between that the first pads 120 and the second mask pattern MP2 or between the second pads 130 and the second mask pattern MP2, for example between lateral surfaces of the first pads 120 and inner lateral surfaces of the pattern holes of the second mask pattern MP2 or between lateral surfaces of the second pads 130 and inner lateral surfaces of the pattern holes of the second mask pattern MP2.

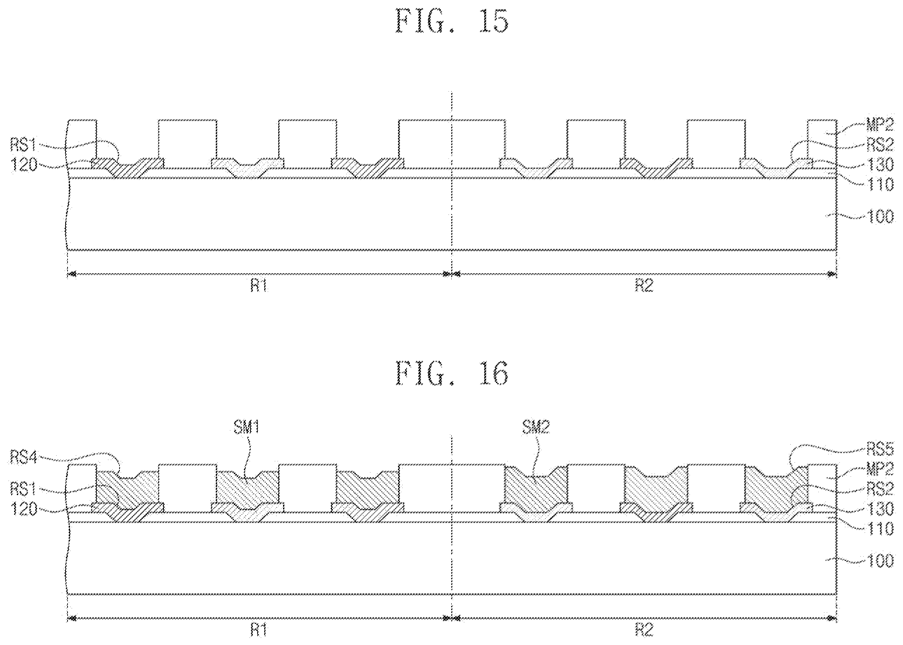

Referring to FIG. 16, first solder material layers SM1 and second solder material layers SM2 may be formed. For example, a plating process may be performed in which the first pads 120 and the second pads 130 exposed by the pattern hole of the second mask pattern MP2 are used as a seed. The plating process may continue until top surfaces of the first solder material layers SM1 and top surfaces of the second solder material layers SM2 reach a certain height in the pattern hole. The first solder material layers SM1 and the second solder material layers SM2 may include a solder material or alloy including tin (Sn).

The first solder material layers SM1 and the second solder material layers SM2 may have their thicknesses greater than those of the first pads 120 and those of the second pads 130. For example, a plating amount of plating process for forming the first solder material layers SM1 and the second solder material layers SM2 may be greater than that of plating process for forming the first pads 120 and the second pads 130.

The thicknesses of the second solder material layers SM2 may be greater than those of the first solder material layers SM1. This may be caused by the fact that, in the plating process, a power applied through the second pads 130 positioned on the second region R2 that corresponds to a peripheral area of the substrate 100 is greater than a power applied to the first pads 120 positioned on the first region R1 that corresponds to a central area of the substrate 100. For example, a large amount of material may be plated on the second pads 130 on the second region R2 where there is a reduced length of electrical path from an external power source. A small amount of material may be plated on the first pads 120 on the first region R1 where there is an increased length of electrical path from an external power source. For example, a volume of each of the second solder material layers SM2 may be greater than that of each of the first solder material layers SM1.

In the plating process, the first recesses RS1 of the first pads 120 may be transferred to the top surfaces of the first solder material layers SM1, and the second recesses RS2 of the second pads 130 may be transferred to the top surfaces of the second solder material layers SM2. For example, fourth recesses RS4 may be formed on the top surfaces of the first solder material layers SM1, and fifth recesses RS5 may be formed on the top surfaces of the second solder material layers SM2. The fifth recesses RS5 may have their widths and depths greater than those of the fourth recesses RS4.

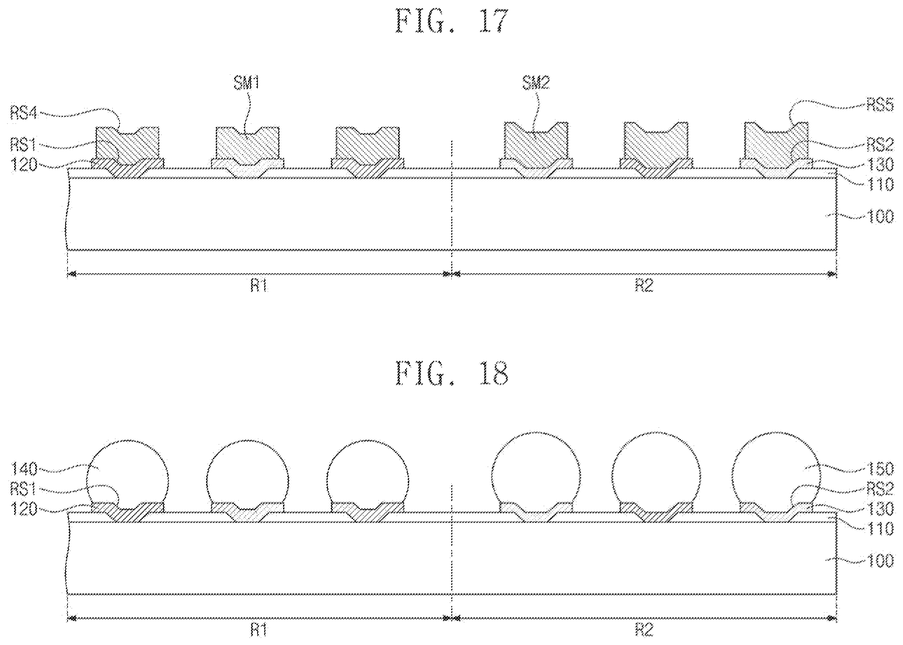

Referring to FIG. 17, the second mask pattern MP2 may be removed. The top surface of the protection layer 110 may be exposed. The first pads 120 and the first solder material layers SM1 thereon may be exposed, and the second pads 130 and the second solder material layers SM2 thereon may be exposed.

Referring to FIG. 18, a reflow process may be performed on the first solder material layers SM1 and the second solder material layers SM2. During the reflow process, the first solder material layers SM1 and the second solder material layers SM2 may be melted, and after the reflow process, the first solder material layers SM1 and the second solder material layers SM2 may be cooled to form first solders 140 and second solders 150.

As the volume of each of the second solder material layers SM2 is greater than that of each of the first solder material layers SM1, each of the second solders 150 may have a volume greater than that of each of the first solders 140.

The solders 140 and 150 formed on the pads 120 and 130 may have different sizes from each other depending on position. For example, a difference in power depending on position may cause that the second solders 150 adjacent to an edge of the substrate 100 are formed larger than the first solders 140 adjacent to a center of the substrate 100. According to some embodiments of the disclosure, the recesses RS1 and RS2 into which the solders 140 and 150 are inserted or introduced may be formed on the pads 120 and 130, and the second recesses RS2 adjacent to the edge of the substrate 100 may have sizes greater than those of the first recesses RS1 adjacent to the center of the substrate 100. Therefore, even though the second solders 150 have their sizes greater than those of the first solders 140, uppermost ends of the second solders 150 may be located at a level the same as or similar to that of uppermost ends of the first solders 140. This configuration may prevent the first solders 140 from failure such as no contact with other apparatus, chip, or device when the substrate 100 is mounted on the other apparatus, chip, or device.

In a semiconductor package according to some embodiments of the disclosure, a volume of each of second solders on a second region may be greater than that of each of first solders on a first region. A volume of an inner section of each of second recesses of second pads may be greater than that of an inner section of each of first recesses of first pads. Therefore, although there is a difference in volume between the first solders and the second solders, upper ends of the second solders may be located at a level the same as or similar to that of upper ends of the first solders. This configuration may prevent the first solders from failure such as no contact with other apparatus, chip, or device when a substrate mounted on the other apparatus, chip, or device, and may provide a semiconductor package having improved structural and operating stability and a method of fabricating a semiconductor package having less process failure.

In addition, heights of solders may be adjusted depending on a distance between a first substrate and a second substrate. This configuration may prevent solders from being in no contact with each other when the first substrate and the second substrate are mounted.

The disclosure have been described in connection with some embodiments of the disclosure illustrated in the accompanying drawings. One of ordinary skill in the art that variations in form and detail may be made therein without departing from the spirit and essential feature of the disclosure. The above disclosed embodiments should thus be considered illustrative and not restrictive.

What is claimed is:

1. A semiconductor package comprising:
a first substrate that comprises a central area and a peripheral area surrounding the central area;
a first pad on the first substrate in the central area;
a second pad on the first substrate in the peripheral area;
a first solder on and coupled to the first pad; and
a second solder on and coupled to the second pad,
wherein the first pad has a first recess from a top surface of the first pad,
wherein the second pad has a second recess from a top surface of the second pad,
wherein a width of the second recess is greater than a width of the first recess in a first direction, and
wherein a volume of the second solder is greater than a volume of the first solder.

2. The semiconductor package of claim 1, wherein a distance from a lateral surface of the second pad to the second recess is in a range of about 2 micrometers to about 5 micrometers.

3. The semiconductor package of claim 1, wherein each of the first recess and the second recess has a circular planar shape, a tetragonal planar shape, a polygonal planar shape, or a cross planar shape.

4. The semiconductor package of claim 1, wherein a height of the first pad and a height of the second pad are the same.

5. The semiconductor package of claim 1, wherein a height of the first solder is about 90% to about 100% of a height of the second solder.

6. The semiconductor package of claim 1, wherein a depth of the second recess is greater than a depth of the first recess.

7. The semiconductor package of claim 1, wherein a volume of an inner section of the second recess is greater than a volume of an inner section of the first recess.

8. The semiconductor package of claim 1, further comprising:
a third pad on the first substrate; and
a third solder on and coupled to the third pad,
wherein the first substrate further comprises an intermediate area between the central area and the peripheral area,
wherein the third pad is in the central area,
wherein the third pad has a third recess from a top surface of the third pad,
wherein a width of the third recess is greater than the width of the first recess and is smaller than the width of the second recess in the first direction.

9. The semiconductor package of claim 8, wherein a volume of the third solder is greater than the volume of the first solder and is less than the volume of the second solder.

10. The semiconductor package of claim 1, further comprising:
a second substrate on the first substrate; and
a fourth pad and a fifth pad on the second substrate,
wherein the first solder connects the first pad to the fourth pad,
wherein the second solder connects the second pad to the fifth pad,
wherein a distance between the first substrate and the second substrate in the central area is about 90% to about 100% of a distance between the first substrate and the second substrate in the peripheral area.

11. A semiconductor package comprising:
a semiconductor chip that has a first region and a second region spaced apart from the first region;
a first pad on the semiconductor chip in the first region;
a second pad on the semiconductor chip in the second region;
a first solder on and coupled to the first pad; and
a second solder on and coupled to the second pad,
wherein the first pad has a first recess from a top surface of the first pad,
wherein the second pad has a second recess from a top surface of the second pad,
wherein a volume of an inner section of the second recess is greater than a volume of an inner section of the first recess, and
wherein a height of the first solder is about 90% to about 100% of a height of the second solder.

12. The semiconductor package of claim 11, wherein a width of the second recess is greater than a width of the first recess.

13. The semiconductor package of claim 11, wherein a volume of the second solder is greater than a volume of the first solder.

14. The semiconductor package of claim 11, wherein a distance from a lateral surface of the second pad to the second recess is in a range of about 2 micrometers to about 5 micrometers.

15. The semiconductor package of claim 11, wherein each of the first recess and the second recess has a circular planar shape, a tetragonal planar shape, a polygonal planar shape, or a cross planar shape.

16. The semiconductor package of claim 11, wherein a height of the first pad and a height of the second pad are the same.

17. The semiconductor package of claim 11, wherein a depth of the second recess is greater than a depth of the first recess.

18. A semiconductor package comprising:
a first substrate;
a plurality of first pads on the first substrate;
a second substrate on the first substrate;
a plurality of second pads on the second substrate; and
a plurality of solders that respectively connect the plurality of first pads to the plurality of second pads,
wherein the plurality of first pads have recesses from top surfaces of the first pads,
wherein widths of the recesses increase in a direction from a center of the first substrate toward an outer lateral surface of the first substrate, and
wherein heights of the plurality of solders increase in the direction from the center of the first substrate toward the outer lateral surface of the first substrate.

19. The semiconductor package of claim 18, wherein a distance from lateral surfaces of the plurality of first pads to the recesses is in a range of about 2 micrometers to about 5 micrometers.

20. The semiconductor package of claim 18, wherein volumes of the solders increase in the direction from the center of the first substrate to the outer lateral surface of the first substrate.
